(19) United States
(12) Patent Application Publication
(10) Pub. No.: US 2012/0037907 A1
(43) Pub. Date: Feb. 16, 2012

(54) Method of Forming Source and Drain Electrodes of Organic Thin Film Transistors by Electroless Plating

(75) Inventors: Gregory Whiting, Mountain View, CA (US); Jeremy Burroughes, Cambridgeshire (GB); Julian Carter, Cambridgeshire (GB); Jonathan Halls, Cambridge (GB); Karl Weber, Victoria (AU)

(73) Assignee: Cambridge Display Technology Limited, Cambridgeshire (GB)

(21) Appl. No.: 13/144,110

(22) PCT Filed: Jan. 27, 2010
(86) PCT No.: PCT/GB2010/000120

§ 371 Date: Oct. 28, 2011

(30) Foreign Application Priority Data
Jan. 30, 2009 (GB) 0901578.5

(51) Int. Cl. H01L 29/786; H01L 21/336

(52) U.S. Cl. 257/57; 438/158; 438/197; 257/E21.411; 257/E29.273

(57) ABSTRACT

A method of manufacturing an organic thin film transistor, the method comprising: depositing a source and drain electrode over a substrate using a solution processing technique; forming a workfunction modifying layer over the source and drain electrodes using a solution processing technique; and depositing an organic semi-conductive material in a channel region between the source and drain electrode using a solution processing technique.

### FIELD OF INVENTION

Aspects of the present invention relates to organic thin film transistors and methods of making the same.

### BACKGROUND OF THE INVENTION

Transistors can be divided into two main types: bipolar junction transistors and field-effect transistors. Both types share a common structure comprising three electrodes with a semi-conductive material disposed therebetween in a channel region. The three electrodes of a bipolar junction transistor are known as the emitter, collector and base, whereas in a field-effect transistor the three electrodes are known as the source, drain and gate. Bipolar junction transistors may be described as current-operated devices as the current between the emitter and collector is controlled by the current flowing between the base and emitter. In contrast, field-effect transistors may be described as voltage-operated devices as the current flowing between source and drain is controlled by the voltage between the gate and the source.

Transistors can also be classified as p-type and n-type according to whether they comprise semi-conductive material which conducts positive charge carriers (holes) or negative charge carriers (electrons) respectively. The semi-conductive material may be selected according to its ability to accept, conduct, and donate charge. The ability of the semi-conductive material to accept, conduct, and donate holes or electrons can be enhanced by doping the material. The material used for the source and drain electrodes can also be selected according to its ability to accept and inject holes or electrons. For example, a p-type transistor device can be formed by selecting a semi-conductive material which is efficient at accepting, conducting, and donating holes, and selecting a material for the source and drain electrodes which is efficient at injecting and accepting holes from the semi-conductive material. Good energy-level matching of the Fermi-level in the electrodes with the HOMO level of the semi-conductive material can enhance hole injection and acceptance. In contrast, an n-type transistor device can be formed by selecting a semi-conductive material which is efficient at accepting, conducting, and donating electrons, and selecting a material for the source and drain electrodes which is efficient at injecting electrons into, and accepting electrons from, the semi-conductive material. Good energy-level matching of the Fermi-level in the electrodes with the LUMO level of the semi-conductive material can enhance electron injection and acceptance.

Transistors can be formed by depositing the components in thin films to form thin film transistors. When an organic material is used as the semi-conductive material in such a device, it is known as an organic thin film transistor.

Various arrangements for organic thin film transistors are known. One such device is an insulated gate field-effect transistor which comprises source and drain electrodes with a semi-conductive material disposed therebetween in a channel region, a gate electrode disposed adjacent the semi-conductive material and a layer of insulting material disposed between the gate electrode and the semi-conductive material in the channel region.

An example of such an organic thin film transistor is shown in FIG. 1. The illustrated structure may be deposited on a substrate (not shown) and comprises source and drain electrodes 2, 4 which are spaced apart with a channel region 6 located therebetween. An organic semiconductor (OSC) 8 is deposited in the channel region 6 and may extend over at least a portion of the source and drain electrodes 2, 4. An insulating layer 10 of dielectric material is deposited over the organic semi-conductor 8 and may extend over at least a portion of the source and drain electrodes 2, 4. Finally, a gate electrode 12 is deposited over the insulating layer 10. The gate electrode 12 is located over the channel region 6 and may extend over at least a portion of the source and drain electrodes 2, 4.

The structure described above is known as a top-gate organic thin film transistor as the gate is located on a top side of the device. Alternatively, it is also known to provide the gate on a bottom side of the device to form a so-called bottom-gate organic thin film transistor.

An example of such a bottom-gate organic thin film transistor is shown in FIG. 2. In order to more clearly show the relationship between the structures illustrated in FIGS. 1 and 2, like reference numerals have been used for corresponding parts. The bottom-gate structure illustrated in FIG. 2 comprises a gate electrode 12 deposited on a substrate 1 with an insulating layer 10 of dielectric material deposited thereover. Source and drain electrodes 2, 4 are deposited over the insulating layer 10 of dielectric material. The source and drain electrodes 2, 4 are spaced apart with a channel region 6 located therebetween over the gate electrode. An organic semiconductor (OSC) 8 is deposited in the channel region 6 and may extend over at least a portion of the source and drain electrodes 2, 4.

One of the challenges with all organic thin film transistors is to ensure a good ohmic contact between the source and drain electrodes and the organic semiconductor (OSC). This is required to minimise contact resistance when the thin film transistor is switched on. A typical approach to minimise extraction and injection barriers, for a p-channel device, is to choose a material for the source and drain electrodes that has a work function that is well matched to the HOMO level of the OSC. For example, many common OSC materials have a good HOMO level matching with the work function of gold, making gold a relatively good material for use as the source and drain electrode material. Similarly, for an n-channel device, a typical approach to minimise extraction and injection barriers is to choose a material for the source and drain electrodes that has a work function that is well matched to the LUMO level of the OSC.

One problem with the aforementioned arrangement is that a relatively small number of materials will have a work function which has a good energy level match with the HOMO/LUMO of the OSC. Many of these materials may be expensive, such as gold, and/or may be difficult to deposit to form the source and drain electrodes. Vapour deposition or sputtering techniques are general used for such materials which require complicated devices such as vacuum equipment. Furthermore, even if a suitable material is available, it may not be perfectly matched for a desired OSC, and a change in the OSC may require a change in the material used for the source and drain electrodes.

Rather than using a vapour deposition or sputtering technique for deposition of source, drain or gate electrodes in an organic thin film transistor, WO 2005/079126 proposes a solution processing technique, in particular, an electroless plating technique. While WO 2005/079126 suggests that this technique could be used for any of the source, drain or gate electrodes, in the example described in WO 2005/079126 the electroless plating technique is only used for the gate electrode while the source and drain are described as comprising a conducting polymer or a metallic material which is deposited through solution processing techniques such as spin, dip, blade, bar, slot-die, or spray coating, inkjet, gravure, offset or screen printing, or by evaporation and photolithography techniques.

The present applicant has found that solution processing techniques, including electroless printing as well as the coating and printing techniques listed immediately above, do not result in source and drain electrodes which have a good ohmic contact with the overlying organic semiconductor (OSC).

EP 1508924 also discloses the use of an electroless plating technique for forming source and drain electrodes of an organic thin film transistor and solves the aforementioned problem of poor ohmic contact by forming an oxide layer over the source and drain electrodes. Two embodiments are described for forming the oxide layer. In a first embodiment the oxide layer is deposited by laser ablation, sputtering, chemical vapour deposition, or vapour deposition. In a second embodiment the oxide layer is formed by oxidizing the surface of the source and drain using an oxygen plasma treatment, thermal oxidation, or anode oxidation. While these techniques may improve ohmic contact between the source and drain electrodes and the organic semiconductor, they lead back to the problem that such techniques general require complicated devices such as vacuum equipment.

WO 01/01502 solves the problem of poor ohmic contact between the source and drain electrodes and the organic semiconductor of an organic thin film transistor by providing a charge transport material which forms a self-assembled layer over the source and drain electrodes. No details are given regarding the techniques used for depositing the various components of the organic thin film transistor. Given that standard gold electrodes and a pentacene organic semiconductor are described in WO 01/01502 it may be assumed that standard vacuum deposition techniques were used for all the components.

US 2005/133782 solves the problem of poor ohmic contact between the source and drain electrodes and the organic semiconductor of an organic thin film transistor by depositing source/drain palladium metal by thermal evaporation, electron beam vapour deposition, or sputtering, and then doping the source/drain palladium metal using a benzo-nitrile or substituted benzo nitriles such as Tetracyanoquinodimethane (TCNQ).

### SUMMARY OF THE INVENTION

The present applicant has realized that none of the prior art arrangements provides a method or device which combines the requirements of an easy, quick and cheap manufacturing process which does not require complicated manufacturing equipment and which results in a device which has good functional properties. Accordingly, it is an aim of embodiments of the present invention to provide such a combination of advantageous features and in particular to provide methods of manufacturing an organic thin film transistor which are easy, quick, cheap, do not require complicated manufacturing equipment, and which result in a device which has good functional properties.

In light of the above, and in accordance with a first aspect of the present invention there is provided a method of manufacturing an organic thin film transistor, the method comprising: depositing a source and drain electrode over a substrate using a solution processing technique; forming a workfunction modifying layer over the source and drain electrodes using a solution processing technique; and depositing an organic semi-conductive material in a channel region between the source and drain electrode using a solution processing technique.

The present applicant has found that the aforementioned method enables a fully solution processed organic thin film transistor to be manufactured which also has good functional properties. While not been bound by theory, it is postulated that solution processing of the source and drain electrodes produces source and drain electrodes having a large surface area at a microscopic level on which a larger amount of workfunction modifying material can be adhered using a further solution processing technique when compared with, for example, vapour deposition or sputtering of the source and drain electrodes and/or the workfunction modifying layer. In turn, a larger contact surface area on a microscopic level is achieved for the workfunction modifying layer such that when an organic semiconductor is solution processed thereover, better charge transfer between the workfunction modifying layer and the organic semiconductor is achieved, for example, by a higher level of doping of the organic semiconductor around the source and drain electrode surfaces.

At the same time, using solution processing techniques for all of the source and drain electrodes, the workfunction modifying layer and the OSC appears to yield coherent layers, each layer fully covering the underlying layer without gaps or holes. One possible problem with using vapour deposition or oxidation techniques for one or more of the layers is that the workfunction modifying layer may not completely cover the electrode surfaces and there may be gaps or holes where the organic semiconductor directly contacts the source and drain leading to degradation in device performance. For example, if a workfunction modifying layer is deposited by vapour deposition over a high surface area source and drain electrode formed by a solution processing technique, on a microscopic level some of the surface of the source and drain electrode will remain uncovered. Further still, if a high energy process is used to deposit the organic semiconductor then this may damage the underlying workfunction modifying layer, again exposing the source and drain to direct contact with the organic semiconductor in a plurality of microscopic areas. By using soft, low energy solution processing techniques for all the layers, high surface area layers are produced with few defects leading to good functional properties in the resultant device. Further still, these advantageous device features are achieved without requiring complicated vapour deposition apparatus or the like in the manufacturing processes.

Various solution processing techniques may be used for each of the layers including techniques selected from electroless plating, electro plating, spin, dip, blade, bar, slot-die, or spray coating, and inkjet, gravure, offset or screen printing.

In one preferred embodiment electroless plating is used to form the source and drain electrodes. This is a low cost and relatively quick method for forming the source and drain electrodes. Several electroless plating techniques are known in the art, any of which may be used. Generally they involve forming a patterned seed layer over the substrate and then exposing the patterned seed layer to an electroless plating solution containing a metal which is deposited on the patterned seed layer.

The patterned seed layer may be formed by depositing a precursor/catalyst on the substrate and then patterning. Alternatively, the precursor/catalyst may be deposited using a direct patterning technique such as inkjet printing or another direct printing technique such as screen printing, flexographic, gravure or the like. It is preferred that none of the seed layer remains exposed, at least in active regions of the device, after electroless plating. That is, after patterning, it is preferred that no material of the seed layer remains between the pattern such that after plating all the seed layer is disposed under the electrodes. If any seed layer remains outside the electrodes after plating, for example in the channel region between the source and drain, then this can adversely affect the functional properties of the resultant device which is very sensitive to materials disposed around the surface of the electrodes and between the electrodes in the channel region of the device.

Various metals can be deposited by electroless plating including copper, nickel, platinum, palladium, cobalt, and gold. In accordance with one embodiment of the present invention copper is used for the source and drain electrodes as it is cheap and readily depositable using an electroless plating technique. Although the present applicant has found that electroless plated copper forms a poor ohmic contact with organic semiconductor when used alone, good performance has been achieved when used in conjunction with a solution processed workfunction modifier. Furthermore, it has been found that copper complexes with solution processable workfunction modifiers allowing selective bonding of the workfunction modifiers to the source and drain electrodes during solution processing of the workfunction modifying layer.

Preferably the source and drain electrodes are cleaned prior to forming the workfunction modifying layer. Dilute acids, such as dilute HCl, have been found to be particularly effective for cleaning electroless plated metals such as copper such that a complete workfunction modifying layer is formed thereover with little in the way of microscopic defects or holes.

The workfunction modifying layer may comprise any solution processable material which improves ohmic contact with an overlying organic semiconductor.

In one arrangement, the workfunction modifying layer is a further metallic layer. This may be deposited by electroless or electro plating. For example, the bulk of the source and drain electrodes can be formed by electroless plating a relatively cheap, high conductivity metal such as copper, and then a surface layer of a metal which forms a better ohmic contact with OSC material, such as gold or palladium, can be deposited thereover.

In another arrangement the workfunction modifying layer is formed of an organic dopant for chemically doping the organic semi-conductive material by accepting or donating charge.

The dopant may be electron-accepting for accepting electrons from the organic semi-conductive material whereby the organic semi-conductive material is p-doped. Preferably, a p-dopant has a LUMO level less than −4.3 eV in order to readily accept electrons. The organic semi-conductive material for use with a p-dopant may have a HOMO level greater than or equal to −5.5 eV in order to donate electrons. Most preferably, for p-channel devices, the dopant has a LUMO level less than −4.3 eV and the organic semi-conductive material has a HOMO level greater than or equal to −5.5 eV.

To avoid any misunderstanding in relation to these negative values, the range “greater than or equal to −5.5 eV” encompasses −5.4 eV and excludes −5.6 eV, and the range “less than −4.3 eV” encompasses −4.4 eV and excludes −4.2 eV.

It has been found that the combination of a semi-conductive organic material having a HOMO level greater than or equal to −5.5 eV and a dopant having a LUMO level less than −4.3 eV results in a conductive composition in the regions of source and drain contacts. While not been bound by theory, it is postulated that an organic semi-conductive material having a HOMO level of greater than or equal to −5.5 eV provides excellent hole transport and injection properties while the dopant having a LUMO level less than −4.3 eV readily accept electrons from such an organic semi-conductive material in order to create free holes in the organic semi-conductive material.

In the case of a p-dopant, the HOMO of the organic semi-conductive material is preferably higher (i.e. less negative) than the LUMO of the dopant. This provides better electron transfer from the HOMO of the organic semi-conductive material to the LUMO of the dopant. However, charge transfer is still observed if the HOMO of the organic semi-conductive material is only slightly lower than the LUMO of the dopant.

Preferably the organic semi-conductive material for a p-type device has a HOMO in the range 4.6-5.5 eV. This allows for good hole injection and transport from the electrodes and through the organic semi-conductive material.

Preferably, the dopant is a charge neutral dopant, most preferably optionally substituted tetracyanoquinodimethane (TCNQ), rather than an ionic species such as protonic acid doping agents. Providing a high concentration of acid adjacent the electrodes may cause etching of the electrodes with the release of electrode material which may degrade the overlying organic semi-conductive material. Furthermore, the acid may interact with organic semi-conductive material resulting in charge separation which is detrimental to device performance. As such, a charge neutral dopant such as TCNQ is preferred.

Preferably, the optionally substituted TCNQ is a fluorinated derivative, for example, tetrafluoro-tetracyanoquinodimethane (F4-TCNQ). It has been found that this derivative is particularly good at accepting electrons.

The conductivity of the organic semiconductor is preferably in the range 10⁻⁶ S/cm to 10⁻² S/cm adjacent the electrodes. However, the conductivity of the compositions can be readily varied by altering the concentration of dopant, or by using a different organic semiconductive material and/or dopant, according to the particular conductivity value desired for a particular use.

As an alternative to the above described p-channel devices, the dopant may be electron-donating for donating electrons to the organic semi-conductive material whereby the organic semi-conductive material is n-dope.

The organic dopant may comprise a dopant moiety for chemically doping an organic semi-conductive material by accepting or donating charge and a separate attachment moiety bonded to the dopant moiety for selectively bonding to the source and drain electrodes. The attachment moiety may comprise a leaving group such that the attachment moiety reacts with the material of the source and drain to from a bond therewith when said group leaves. For example, the attachment moiety may comprise at least one of a silyl group, a thiol group, an amine group and a phosphate group.

A spacer group may be provided between the attachment moiety and the dopant moiety. The spacer groups can be used to better dispose the dopant moieties within the OSC leading to better doping. Furthermore, the spacer groups can provide some flexibility in the surface onto which the OSC is to be deposited which can result in better film formation of the OSC thereon. The spacer group may be an alkylene chain, e.g. a C₁-C₂₀ alkylene chain. The spacer groups may be of different lengths so as to form a concentration gradient of dopant moiety which increases on approaching the source and drain electrodes.

The organic dopant may form a thin self-assembled layer such as a self assembled mono-layer (SAM), e.g. a thiol such as pentafluoro-phenyl thiol.

The organic semi-conductive material may be a solution processable polymer, dendrimer or small molecule.

For a bottom-gate device an organic dielectric material may be utilized to provide a large differential in the chemical properties of the dielectric layer and the source and drain electrodes such that selective binding of the attachment moiety to the source and drain electrodes is encouraged.

Similarly, for a top-gate device an organic substrate may be utilized to provide a large differential in the chemical properties of the dielectric layer and the source and drain electrodes such that selective binding of the attachment moiety to the source and drain electrodes is encouraged.

In another arrangement, the dielectric layer or the substrate may be treated to enhance the selective binding of the attachments moiety to the source and drain electrodes as opposed to the dielectric layer or the substrate.

Preferably the dielectric layer is deposited by one of the previously mentioned solution processing techniques. Further still, the gate dielectric may also be deposited using one of the previously mentioned solution processing techniques. Accordingly, it is possible to form a fully solution processed organic thin film transistor with good functional properties.

According to another aspect of the present invention, there is provided an organic thin film transistor formed according to the previously described methods. The organic thin film transistor comprises: a solution processed source and drain electrode; a solution processed workfunction modifying material disposed over the source and drain electrode; and a solution processed organic semi-conductive material disposed between the source and drain electrodes in a channel region. If the source and drain electrodes are deposited using the preferred electroless plating technique then they will comprises seed material disposed within the electrode metal.

### SUMMARY OF THE DRAWINGS

The present invention will now be described in further detail, by way of example only, with reference to the accompanying drawings in which:

FIG. 1 shows a known top-gate organic thin film transistor arrangement;

FIG. 2 shows a known bottom-gate organic thin film transistor arrangement;

FIG. 3 shows an organic thin film transistor according to an embodiment of the present invention;

FIG. 4 illustrates an electroless plating technique;

FIG. 5 illustrates the method steps involved in forming an organic thin film transistor according to the embodiment illustrated in FIG. 3;

FIG. 6 shows a pixel comprising an organic thin film transistor and an adjacent organic light emitting device fabricated on a common substrate; and

FIG. 7 shows a pixel comprising an organic thin film transistor fabricated in a stacked relationship with an organic light emitting device.

### DETAILED DESCRIPTION OF PREFERRED EMBODIMENTS

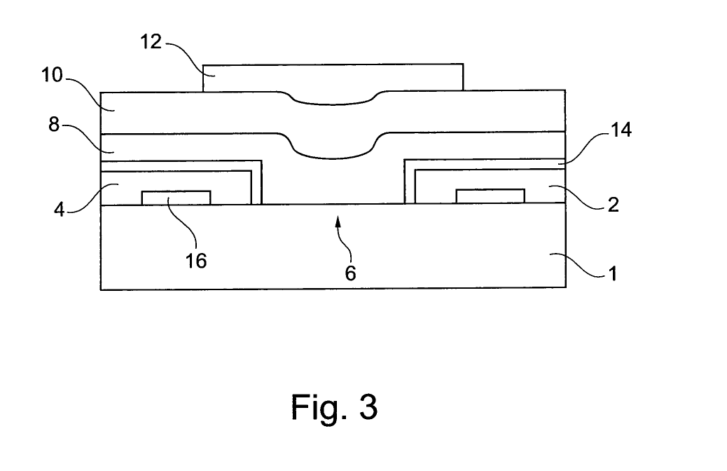

FIG. 3 shows a top-gate organic thin film transistor according to an embodiment of the present invention. The device comprises a substrate 1 on which source and drain electrodes 2, 4 are spaced apart with a channel region 6 located therebetween. An organic semiconductor (OSC) 8 is deposited in the channel region 6 and may extend over at least a portion of the source and drain electrodes 2, 4. An insulating layer 10 of dielectric material is deposited over the organic semi-conductor 8 and may extend over at least a portion of the source and drain electrodes 2, 4. Finally, a gate electrode 12 is deposited over the insulating layer 10. The gate electrode 12 is located over the channel region 6 and may extend over at least a portion of the source and drain electrodes 2, 4.

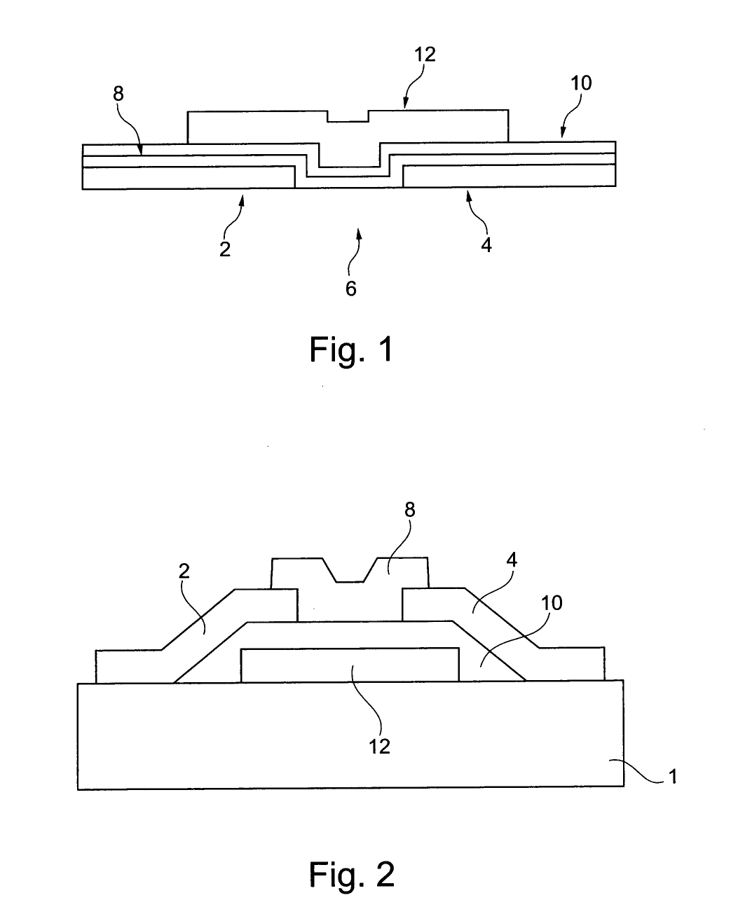

The structure is similar to the prior art arrangement shown in FIG. 1 and for clarity like reference numerals have been used for like parts. One key difference of the arrangement shown in FIG. 3 is that the source and drain electrodes 2, 4 have disposed thereon a workfunction modifying layer 14. A further difference is that all of the source and drain electrodes 2, 4, the workfunction modifying layer 14, and the organic semi-conductor 8 have been solution processed. This may be ascertained by microscopic analysis of the layers. For example, in the case that the source and drain electrodes are deposited by the preferred electroless plating technique then they comprise seed material 16 disposed within the electrodes.

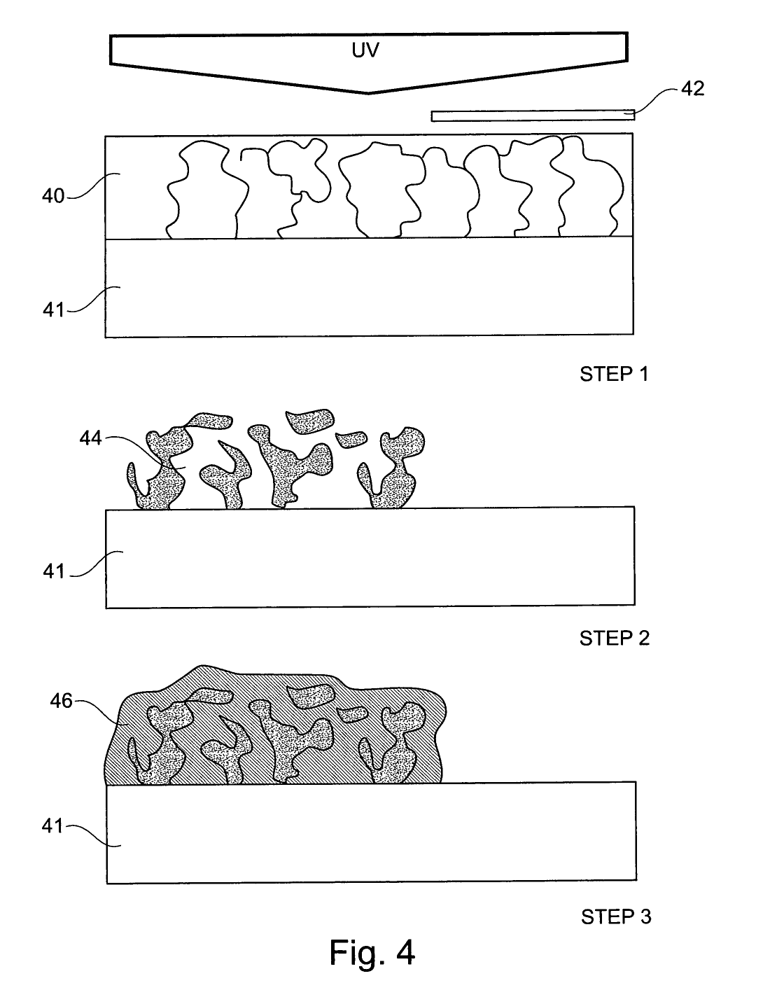

A method for forming a patterned seed layer for electroless plating of the source and drain electrodes is illustrated in FIG. 4. A mixture of electroless plating catalyst and soluble component 40 is deposited by, for example, spin coating on a substrate 41. The deposited mixture is selectively UV exposed using, for example, a mask 42 as shown in Step 1, then developed and the soluble component removed to leave the patterned seed layer 44 as shown in Step 2. The substrate with patterned seed layer may then be placed in a tank with electroless plating solution such that metal from the solution grows over the patterned seed layer to form electrodes 46 in which the seed material is disposed.

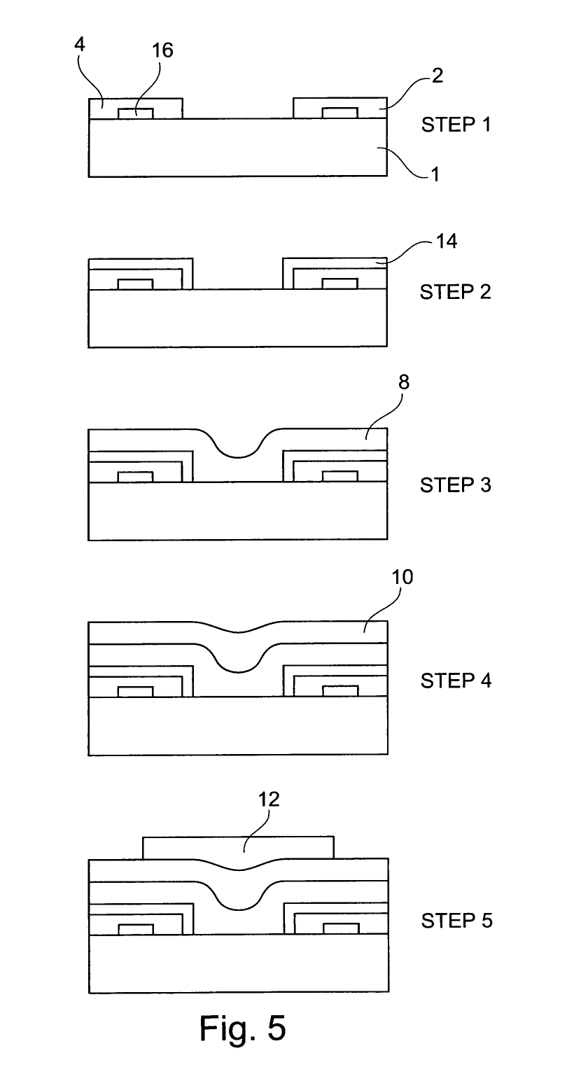

Following electroless plating to form the source and drain electrodes, the remaining layers of the OTFT are fabricated. The OTFT manufacturing process is illustrated in FIG. 5.

In Step 1 the source and drain electrodes 2, 4 are formed on a substrate 1 using a patterned seed layer 16 as previously described. The substrate is preferrably cleaned with dilute HCl to remove any native oxide. In Step 2 an F4TCNQ layer 14 is applied from ortho-chlorobenzene solution and the solution is then rinsed off. The F4TCNQ 14 complexes with the source and drain electrodes 2, 4. In Step 3 OSC 8 is deposited by spin coating and dried. In Step 4 dielectric 10 is spin coated and dried. Finally, in Step 5a gate electrode 12 is formed.

This technique is also compatible with bottom-gate devices. In this case, the gate electrode is deposited first and covered with a gate dielectric. The source and drain electrodes are then deposited thereover and coated with a workfunction modifying layer. Finally, the OSC is deposited.

A treatment may be applied in specific locations to prevent attachment of the workfunction modifying material. This may be required to prevent attachment to the channel region if selectively cannot be achieved directly.

Where the source-drain metal needs to be exposed (e.g. for electrical connection to a subsequent conducting layer) the workfunction modifying layer may need to be removed (e.g. by direct photo-patterning of a photo-reactive attachment group, laser ablation, etc) or prior surface patterning may be required to define where the workfunction modifying layer is required. Alternatively, if the workfunction modifying layer is thin and conducting enough, it can be left in situ without impeding conducting via formation.

Other features of organic thin film transistors according to embodiments of the present invention are discussed below.

### Substrate

The substrate may be rigid or flexible. Rigid substrates may be selected from glass or silicon and flexible substrates may comprise thin glass or plastics such as poly(ethylene terephthalate) (PET), poly(ethylene-naphthalate) PEN, polycarbonate and polyimide.

The organic semiconductive material may be made solution processable through the use of a suitable solvent. Exemplary solvents include mono- or poly-alkylbenzenes such as toluene and xylene; tetralin; and chloroform. Preferred solution deposition techniques include spin coating and ink jet printing. Other solution deposition techniques include dip-coating, roll printing and screen printing.

### Organic Semiconductor Materials

Preferred organic semiconductor materials include small molecules such as optionally substituted pentacene; optionally substituted polymers such as polyarylenes, in particular polyfluorenes and polythiophenes; and oligomers. Blends of materials, including blends of different material types (e.g. a polymer and small molecule blend) may be used.

### Source and Drain Electrodes

The source and drain electrodes comprise solution processable material which may be in the form of a metal or a conductive polymer. In preferred embodiments of the present invention the source and drain electrodes are formed by electroless plating of a metal.

The source and drain electrodes are preferably formed from the same material for ease of manufacture. However, it will be appreciated that the source and drain electrodes may be formed of different materials and/or thicknesses for optimisation of charge injection and extraction respectively.

The length of the channel defined between the source and drain electrodes may be up to 500 microns, but preferably the length is less than 200 microns, more preferably less than 100 microns, most preferably less than 20 microns.

### Gate Electrode

The gate electrode 4 can be selected from a wide range of conducting materials for example a metal (e.g. gold) or metal compound (e.g. indium tin oxide). Alternatively, conductive polymers may be deposited as the gate electrode 4. Such conductive polymers may be deposited from solution using, for example, spin coating or ink jet printing techniques and other solution deposition techniques discussed above

Thicknesses of the gate electrode, source and drain electrodes may be in the region of 5-200 nm, although typically 50 nm as measured by Atomic Force Microscopy (AFM), for example.

### Insulating Layer

The insulating layer comprises a dielectric material selected from insulating materials having a high resistivity. The dielectric constant, k, of the dielectric is typically around 2-3 although materials with a high value of k are desirable because the capacitance that is achievable for an OTFT is directly proportional to k, and the drain current I_{D} is directly proportional to the capacitance. Thus, in order to achieve high drain currents with low operational voltages, OTFTs with thin dielectric layers in the channel region are preferred.

The dielectric material may be organic or inorganic. Preferred inorganic materials include SiO₂, SiNₓ and spin-on-glass (SOG). Preferred organic materials are generally polymers and include insulating polymers such as poly vinylalcohol (PVA), polyvinylpyrrolidine (PVP), acrylates such as polymethylmethacrylate (PMMA) and benzocyclobutanes (BCBs) available from Dow Corning. The insulating layer may be formed from a blend of materials or comprise a multi-layered structure.

The dielectric material may be deposited by thermal evaporation, vacuum processing or lamination techniques as are known in the art. Alternatively, the dielectric material may be deposited from solution using, for example, spin coating or ink jet printing techniques and other solution deposition techniques discussed above.

If the dielectric material is deposited from solution onto the organic semiconductor, it should not result in dissolution of the organic semiconductor. Likewise, the dielectric material should not be dissolved if the organic semiconductor is deposited onto it from solution. Techniques to avoid such dissolution include: use of orthogonal solvents, that is use of a solvent for deposition of the uppermost layer that does not dissolve the underlying layer; and crosslinking of the underlying layer.

The thickness of the insulating layer is preferably less than 2 micrometres, more preferably less than 500 nm.

### Further Layers

Other layers may be included in the device architecture. For example, a self assembled monolayer (SAM) may be deposited on the gate, source or drain electrodes, substrate, insulating layer and organic semiconductor material to promote crystallity, reduce contact resistance, repair surface characteristics and promote adhesion where required. In particular, the dielectric surface in the channel region may be provided with a monolayer comprising a binding region and an organic region to improve device performance, e.g. by improving the organic semiconductor's morphology (in particular polymer alignment and crystallinity) and covering charge traps, in particular for a high k dielectric surface. Exemplary materials for such a monolayer include chloro- or alkoxy-silanes with long alkyl chains, eg octadecyltrichlorosilane. Similarly, the source and drain electrodes may be provided with a SAM to improve the contact between the organic semiconductor and the electrodes. For example, gold SD electrodes may be provided with a SAM comprising a thiol binding group and a group for improving the contact which may be a group having a high dipole moment; a dopant; or a conjugated moiety.

### OTFT Applications

OTFTs according to embodiments of the present invention have a wide range of possible applications. One such application is to drive pixels in an optical device, preferably an organic optical device. Examples of such optical devices include photoresponsive devices, in particular photodetectors, and light-emissive devices, in particular organic light emitting devices. OTFTs are particularly suited for use with active matrix organic light emitting devices, e.g. for use in display applications.

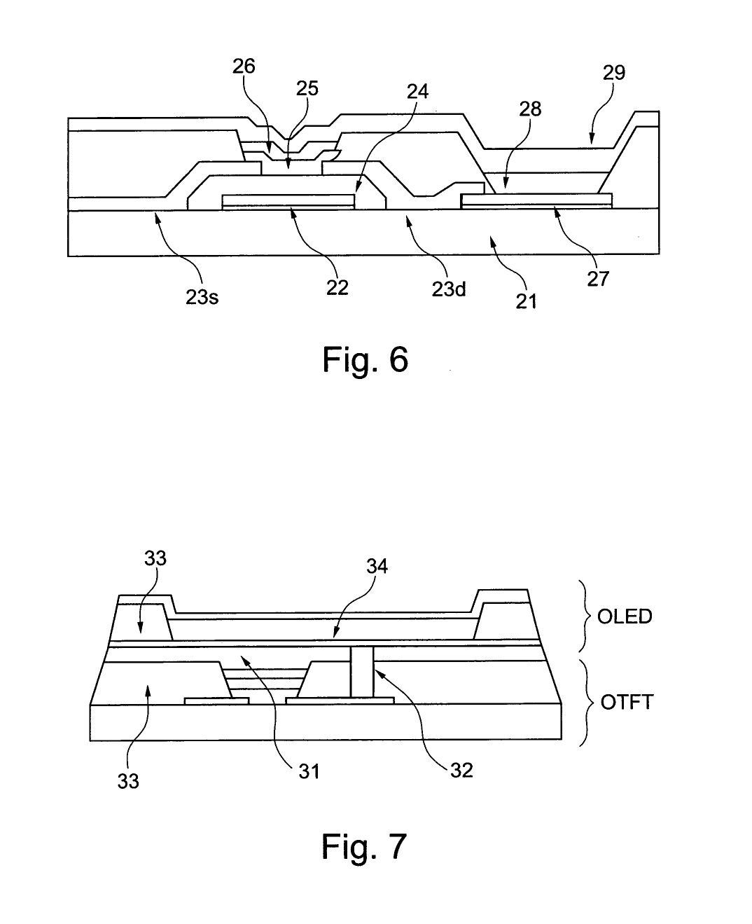

FIG. 6 shows a pixel comprising an organic thin film transistor and an adjacent organic light emitting device fabricated on a common substrate 20. The OTFT comprises gate electrode 22, dielectric layer 24, source and drain electrodes 23s and 23d respectively, and OSC layer 25. The OLED comprises anode 27, cathode 29 and an electroluminescent layer 28 provided between the anode and cathode. Further layers may be located between the anode and cathode, such as charge transporting, charge injecting or charge blocking layers. In the embodiment of FIG. 6, the layer of cathode material extends across both the OTFT and the OLED, and an insulating layer 26 is provided to electrically isolate the cathode layer 29 from the OSC layer 25. The active areas of the OTFT and the OLED are defined by a common bank material formed by depositing a layer of photoresist on substrate 21 and patterning it to define OTFT and OLED areas on the substrate.

In this embodiment, the drain electrode 23d is directly connected to the anode of the organic light emitting device for switching the organic light emitting device between emitting and non-emitting states.

In an alternative arrangement illustrated in FIG. 7, an organic thin film transistor may be fabricated in a stacked relationship to an organic light emitting device. In such an embodiment, the organic thin film transistor is built up as described above in either a top or bottom gate configuration. As with the embodiment of FIG. 6, the active areas of the OTFT and OLED are defined by a patterned layer of photoresist 33, however in this stacked arrangement, there are two separate bank layers 33—one for the OLED and one for the OTFT. A planarisation layer 31 (also known as a passivation layer) is deposited over the OTFT. Exemplary passivation layers include BCBs and parylenes. An organic light emitting device is fabricated over the passivation layer. The anode 34 of the organic light emitting device is electrically connected to the drain electrode of the organic thin film transistor by a conductive via 32 passing through passivation layer 31 and bank layer 33.

It will be appreciated that pixel circuits comprising an OTFT and an optically active area (e.g. light emitting or light sensing area) may comprise further elements. In particular, the OLED pixel circuits of FIGS. 6 and 7 will typically comprise least one further transistor in addition to the driving transistor shown, and at least one capacitor.

It will be appreciated that the organic light emitting devices described herein may be top or bottom-emitting devices. That is, the devices may emit light through either the anode or cathode side of the device. In a transparent device, both the anode and cathode are transparent. It will be appreciated that a transparent cathode device need not have a transparent anode (unless, of course, a fully transparent device is desired), and so the transparent anode used for bottom-emitting devices may be replaced or supplemented with a layer of reflective material such as a layer of aluminium.

Transparent cathodes are particularly advantageous for active matrix devices because emission through a transparent anode in such devices may be at least partially blocked by OTFT drive circuitry located underneath the emissive pixels as can be seen from the embodiment illustrated in FIG. 7.

While this invention has been particularly shown and described with reference to preferred embodiments thereof, it will be understood by those skilled in the art that various changes in form and details may be made therein without departing from the scope of the invention as defined by the appended claims.

1. A method of manufacturing an organic thin film transistor, the method comprising:
depositing a source and drain electrode over a substrate using a solution processing technique;
forming a workfunction modifying layer over the source and drain electrodes using a solution processing technique; and
depositing an organic semi-conductive material in a channel region between the source and drain electrode using a solution processing technique.

2. A method according to claim 1, wherein each of said solution processing techniques is independently selected from the group consisting of electroless plating, electro plating, spin coating, dip coating, blade coating, bar coating, slot-die coating, spray coating, inkjet printing, gravure printing, offset printing, and screen printing.

3. A method according to claim 2, comprising using an electroless plating technique to form the source and drain electrodes.

4. A method according to claim 3, wherein the electroless plating technique comprises forming a seed layer comprising a pattern with no material of the seed layer remaining between the pattern.

5. A method according to claim 4, comprising forming the patterned seed layer by depositing a layer of precursor material on the substrate and then patterning by removing the precursor material from areas between the pattern.

6. A method according to claim 4, comprising forming the patterned seed layer by depositing a layer of precursor material on the substrate using a direct patterning technique.

7. A method according to claim 1, comprising forming the source and drain electrodes from one of copper, nickel, platinum, palladium, cobalt, and gold.

8. A method according to claim 7, comprising forming the source and drain electrodes from copper.

9. A method according to claim 1, comprising cleaning the source and drain electrodes prior to forming the workfunction modifying layer.

10. A method according to claim 9, wherein cleaning comprises washing the source and drain electrodes with a dilute acid.

11. A method according to claim 1, wherein the workfunction modifying layer comprises a metallic layer.

12. A method according to claim 11, comprising depositing the metallic layer by electroless plating or electro plating.

13. A method according to claim 1, wherein the workfunction modifying layer comprises an organic dopant for chemically doping the organic semi-conductive material by accepting or donating charge.

14. A method according to claim 13, wherein the organic dopant is a charge neutral dopant.

15. A method according to claim 13, wherein the organic dopant is electron-accepting for accepting electrons from the organic semi-conductive material whereby the organic semi-conductive material is p-doped.

16. A method according to claim 15, wherein the organic dopant has a LUMO level less than −4.3 eV.

17. A method according to claim 15, wherein the organic semi-conductive material has a HOMO level greater than or equal to −5.5 eV.

18. A method according to claim 15, wherein the HOMO of the organic semi-conductive material is higher than the LUMO of the dopant.

19. A method according to claim 15, wherein the organic semi-conductive material has a HOMO in the range −4.6 to −5.5 eV.

20. A method according to claim 15, wherein the organic dopant is optionally substituted tetracyanoquinodimethane (TCNQ).

21. A method according to claim 20, wherein the optionally substituted TCNQ is a fluorinated derivative thereof.

22. A method according to claim 13, wherein the organic dopant comprises a dopant moiety for chemically doping an organic semi-conductive material by accepting or donating charge and a separate attachment moiety bonded to the dopant moiety for selectively bonding to the source and drain electrodes.

23. A method according to claim 22, wherein a spacer group is provided between the attachment moiety and the dopant moiety.

24. A method according to claim 1, wherein the workfunction modifying layer comprises a self-assembled layer.

25. A method according to claim 1, wherein the organic thin film transistor is a bottom-gate device comprising a gate electrode disposed on the substrate and a layer of dielectric material disposed over the gate electrode, the source and drain electrodes being disposed over the dielectric material.

26. A method according to claim 1, wherein the organic thin film transistor is a top-gate device in which the source and drain electrodes are disposed on the substrate, the organic semi-conductive material is disposed over the source and drain electrodes and in the channel region therebetween, a dielectric material is disposed over the organic semi-conductive material and a gate electrode is disposed over the dielectric material.

27. A method according to claim 25, comprising depositing the dielectric material by a solution processing technique.

28. A method according to any one of claim 25, comprising depositing the gate electrode by a solution processing technique.

29. An organic thin film transistor comprising:
a solution processed source and drain electrode;
a solution processed workfunction modifying material disposed over the source and drain electrode; and
a solution processed organic semi-conductive material disposed between the source and drain electrodes in a channel region.

30. An organic thin film transistor according to claim 29, wherein electroless plating seed material is disposed within the source and drain electrodes.
